(19) United States
(12) Patent Application Publication
(10) Pub. No.: US 2026/0147949 A1
(43) Pub. Date: May 28, 2026

(54) GENERATING AGENTS RELATIVE TO A SIMULATED AUTONOMOUS VEHICLE

(71) Applicant: MOTIONAL AD LLC, Boston, MA (US)

(72) Inventor: Thomas Andrew Kirton, Boston, MA (US)

(21) Appl. No.: 19/120,963

(22) PCT Filed: Oct. 12, 2023
(86) PCT No.: PCT/US2023/035045

§ 371 Date: Apr. 14, 2025

Related U.S. Application Data
(60) Provisional application No. 63/416,475, filed on Oct. 14, 2022.

(51) Int. Cl. G06F 30/15

(52) U.S. Cl. CPC G06F 30/15

(57) ABSTRACT

Provided are methods, systems, and storage media for random traffic generation. Methods include determining parameters of a simulation including a volume, simulated agent types, and an simulated agent density. Initiating the simulation by a seed that identifies at least a starting location and a goal location of the simulation. Methods also include assigning goals to simulated agents within the volume, and executing the simulation wherein the volume is updated responsive to motion of the simulated vehicle.

### CROSS-REFERENCE TO RELATED APPLICATIONS

The present application claims priority to U.S. Patent Application No. 63/416,475, filed on Oct. 14, 2022, entitled “Random Traffic Generation,” which is herein incorporated by reference in its entirety.

### BACKGROUND

Autonomous systems obtain data from the surrounding environment and use the data to navigate through the environment. The autonomous systems include subsystems, sensors, and devices that process the data to enable the autonomous system to recognize and understand the environment. Based on the output of the subsystems, sensors, and devices, the autonomous systems make decisions to navigate through the environment.

### BRIEF DESCRIPTION OF THE FIGURES

FIG. 1 is an example environment in which a vehicle including one or more components of an autonomous system can be implemented;

FIG. 2 is a diagram of one or more systems of a vehicle including an autonomous system;

FIG. 3 is a diagram of components of one or more devices and/or one or more systems of FIGS. 1 and 2;

FIG. 4 is a diagram of certain components of an autonomous system;

FIG. 5 shows a diagram of an implementation of generating agents relative to a simulated autonomous vehicle;

FIG. 6 shows a testing infrastructure;

FIG. 7 shows a moving volume with agents generated relative to a simulated autonomous vehicle;

FIG. 8 is a workflow for generating agents relative to a simulated autonomous vehicle; and

FIG. 9 is a process flow diagram of a process that enables generating agents relative to a simulated autonomous vehicle.

### DETAILED DESCRIPTION

In the following description numerous specific details are set forth in order to provide a thorough understanding of the present disclosure for the purposes of explanation. It will be apparent, however, that the embodiments described by the present disclosure can be practiced without these specific details. In some instances, well-known structures and devices are illustrated in block diagram form in order to avoid unnecessarily obscuring aspects of the present disclosure.

Specific arrangements or orderings of schematic elements, such as those representing systems, devices, modules, instruction blocks, data elements, and/or the like are illustrated in the drawings for ease of description. However, it will be understood by those skilled in the art that the specific ordering or arrangement of the schematic elements in the drawings is not meant to imply that a particular order or sequence of processing, or separation of processes, is required unless explicitly described as such. Further, the inclusion of a schematic element in a drawing is not meant to imply that such element is required in all embodiments or that the features represented by such element may not be included in or combined with other elements in some embodiments unless explicitly described as such.

Further, where connecting elements such as solid or dashed lines or arrows are used in the drawings to illustrate a connection, relationship, or association between or among two or more other schematic elements, the absence of any such connecting elements is not meant to imply that no connection, relationship, or association can exist. In other words, some connections, relationships, or associations between elements are not illustrated in the drawings so as not to obscure the disclosure. In addition, for ease of illustration, a single connecting element can be used to represent multiple connections, relationships or associations between elements. For example, where a connecting element represents communication of signals, data, or instructions (e.g., “software instructions”), it should be understood by those skilled in the art that such element can represent one or multiple signal paths (e.g., a bus), as may be needed, to affect the communication.

Although the terms first, second, third, and/or the like are used to describe various elements, these elements should not be limited by these terms. The terms first, second, third, and/or the like are used only to distinguish one element from another. For example, a first contact could be termed a second contact and, similarly, a second contact could be termed a first contact without departing from the scope of the described embodiments. The first contact and the second contact are both contacts, but they are not the same contact.

The terminology used in the description of the various described embodiments herein is included for the purpose of describing particular embodiments only and is not intended to be limiting. As used in the description of the various described embodiments and the appended claims, the singular forms “a,” “an” and “the” are intended to include the plural forms as well and can be used interchangeably with “one or more” or “at least one,” unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this description specify the presence of stated features, integers, steps, operations, elements, and/or components, but do not preclude the presence or addition of one or more other features, integers, steps, operations, elements, components, and/or groups thereof.

As used herein, the terms “communication” and “communicate” refer to at least one of the reception, receipt, transmission, transfer, provision, and/or the like of information (or information represented by, for example, data, signals, messages, instructions, commands, and/or the like). For one unit (e.g., a device, a system, a component of a device or system, combinations thereof, and/or the like) to be in communication with another unit means that the one unit is able to directly or indirectly receive information from and/or send (e.g., transmit) information to the other unit. This may refer to a direct or indirect connection that is wired and/or wireless in nature. Additionally, two units may be in communication with each other even though the information transmitted may be modified, processed, relayed, and/or routed between the first and second unit. For example, a first unit may be in communication with a second unit even though the first unit passively receives information and does not actively transmit information to the second unit. As another example, a first unit may be in communication with a second unit if at least one intermediary unit (e.g., a third unit located between the first unit and the second unit) processes information received from the first unit and transmits the processed information to the second unit. In some embodiments, a message may refer to a network packet (e.g., a data packet and/or the like) that includes data.

As used herein, the term “if” is, optionally, construed to mean “when”, “upon”, “in response to determining,” “in response to detecting,” and/or the like, depending on the context. Similarly, the phrase “if it is determined” or “if [a stated condition or event] is detected” is, optionally, construed to mean “upon determining,” “in response to determining,” “upon detecting [the stated condition or event],” “in response to detecting [the stated condition or event],” and/or the like, depending on the context. Also, as used herein, the terms “has”, “have”, “having”, or the like are intended to be open-ended terms. Further, the phrase “based on” is intended to mean “based at least partially on” unless explicitly stated otherwise.

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments can be practiced without these specific details. In other instances, well-known methods, procedures, components, circuits, and networks have not been described in detail so as not to unnecessarily obscure aspects of the embodiments.

### GENERAL OVERVIEW

In some aspects and/or embodiments, systems, methods, and computer program products described herein include and/or implement random traffic generation. Autonomous systems are developed, tested, and evaluated using simulations. In a simulation, a simulated vehicle under test (e.g., an AV stack or other software of a real-world vehicle) navigates though a simulated environment that includes at least one simulated agent. The simulation is initiated by a seed that identifies at least a starting location of the simulation. A volume, an simulated agent type, and an simulated agent density are defined. The volume is collocated with the simulated vehicle at the starting location. At least one goal is defined for respective simulated agents within the volume. The simulation is executed, and the volume is updated responsive to motion of the simulated vehicle until the simulated vehicle reaches a goal location.

By virtue of the implementation of systems, methods, and computer program products described herein, techniques for random traffic generation randomly spawns one or more simulated agents. The simulated agents are defined within a predetermined range. By simulating agents, a more authentic environment is created for evaluation of the AV. Accordingly, in examples, the simulation creates a realistic digital representation of environments encountered by real world vehicles. Additionally, some of the advantages of these techniques include a randomly generated simulation that is computationally efficient through the use of a volume with variable range based on the location of the simulated vehicle for in a simulation. The randomly generated simulated agents within the volume enable a reduction in noise during simulation from non-relevant simulated agents. The simulated environment according to the present techniques is more realistic than other simulated environments due to randomization of simulated agents, with each simulated agent exhibiting simulated agent awareness.

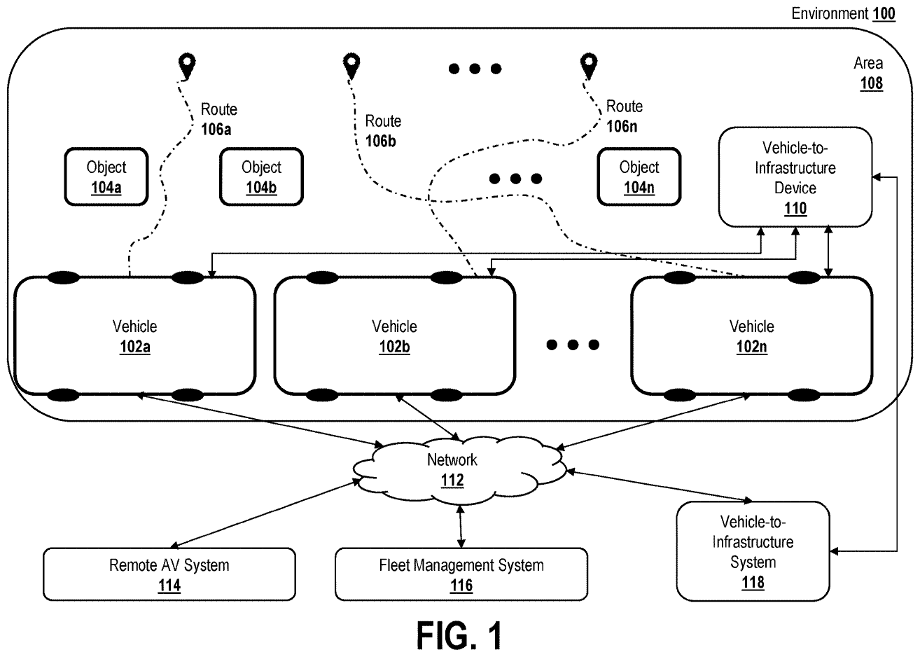

Referring now to FIG. 1, illustrated is example environment 100 in which vehicles that include autonomous systems, as well as vehicles that do not, are operated. As illustrated, environment 100 includes vehicles 102a-102n, objects 104a-104n, routes 106a-106n, area 108, vehicle-to-infrastructure (V2I) device 110, network 112, remote autonomous vehicle (AV) system 114, fleet management system 116, and V2I system 118. Vehicles 102a-102n, vehicle-to-infrastructure (V2I) device 110, network 112, autonomous vehicle (AV) system 114, fleet management system 116, and V2I system 118 interconnect (e.g., establish a connection to communicate and/or the like) via wired connections, wireless connections, or a combination of wired or wireless connections. In some embodiments, objects 104a-104n interconnect with at least one of vehicles 102a-102n, vehicle-to-infrastructure (V2I) device 110, network 112, autonomous vehicle (AV) system 114, fleet management system 116, and V2I system 118 via wired connections, wireless connections, or a combination of wired or wireless connections.

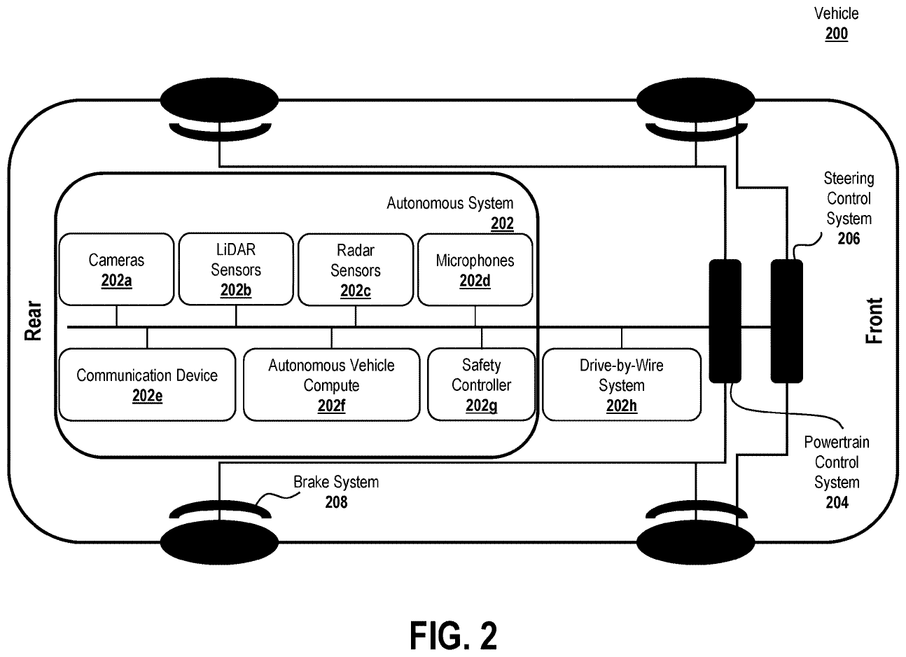

Vehicles 102a-102n (referred to individually as vehicle 102 and collectively as vehicles 102) include at least one device configured to transport goods and/or people. In some embodiments, vehicles 102 are configured to be in communication with V2I device 110, remote AV system 114, fleet management system 116, and/or V2I system 118 via network 112. In some embodiments, vehicles 102 include cars, buses, trucks, trains, and/or the like. In some embodiments, vehicles 102 are the same as, or similar to, vehicles 200, described herein (see FIG. 2). In some embodiments, a vehicle 200 of a set of vehicles 200 is associated with an autonomous fleet manager. In some embodiments, vehicles 102 travel along respective routes 106a-106n (referred to individually as route 106 and collectively as routes 106), as described herein. In some embodiments, one or more vehicles 102 include an autonomous system (e.g., an autonomous system that is the same as or similar to autonomous system 202).

Objects 104a-104n (referred to individually as object 104 and collectively as objects 104) include, for example, at least one vehicle, at least one pedestrian, at least one cyclist, at least one structure (e.g., a building, a sign, a fire hydrant, etc.), and/or the like. Each object 104 is stationary (e.g., located at a fixed location for a period of time) or mobile (e.g., having a velocity and associated with at least one trajectory). In some embodiments, objects 104 are associated with corresponding locations in area 108.

Routes 106a-106n (referred to individually as route 106 and collectively as routes 106) are each associated with (e.g., prescribe) a sequence of actions (also known as a trajectory) connecting states along which an AV can navigate. Each route 106 starts at an initial state (e.g., a state that corresponds to a first spatiotemporal location, velocity, and/or the like) and ends at a final goal state (e.g., a state that corresponds to a second spatiotemporal location that is different from the first spatiotemporal location) or goal region (e.g. a subspace of acceptable states (e.g., terminal states)). In some embodiments, the first state includes a location at which an individual or individuals are to be picked-up by the AV and the second state or region includes a location or locations at which the individual or individuals picked-up by the AV are to be dropped-off. In some embodiments, routes 106 include a plurality of acceptable state sequences (e.g., a plurality of spatiotemporal location sequences), the plurality of state sequences associated with (e.g., defining) a plurality of trajectories. In an example, routes 106 include only high level actions or imprecise state locations, such as a series of connected roads dictating turning directions at roadway intersections. Additionally, or alternatively, routes 106 may include more precise actions or states such as, for example, specific target lanes or precise locations within the lane areas and targeted speed at those positions. In an example, routes 106 include a plurality of precise state sequences along the at least one high level action sequence with a limited lookahead horizon to reach intermediate goals, where the combination of successive iterations of limited horizon state sequences cumulatively correspond to a plurality of trajectories that collectively form the high level route to terminate at the final goal state or region.

Area 108 includes a physical area (e.g., a geographic region) within which vehicles 102 can navigate. In an example, area 108 includes at least one state (e.g., a country, a province, an individual state of a plurality of states included in a country, etc.), at least one portion of a state, at least one city, at least one portion of a city, etc. In some embodiments, area 108 includes at least one named thoroughfare (referred to herein as a “road”) such as a highway, an interstate highway, a parkway, a city street, etc. Additionally, or alternatively, in some examples area 108 includes at least one unnamed road such as a driveway, a section of a parking lot, a section of a vacant and/or undeveloped lot, a dirt path, etc. In some embodiments, a road includes at least one lane (e.g., a portion of the road that can be traversed by vehicles 102). In an example, a road includes at least one lane associated with (e.g., identified based on) at least one lane marking.

Vehicle-to-Infrastructure (V2I) device 110 (sometimes referred to as a Vehicle-to-Infrastructure or Vehicle-to-Everything (V2X) device) includes at least one device configured to be in communication with vehicles 102 and/or V2I infrastructure system 118. In some embodiments, V2I device 110 is configured to be in communication with vehicles 102, remote AV system 114, fleet management system 116, and/or V2I system 118 via network 112. In some embodiments, V2I device 110 includes a radio frequency identification (RFID) device, signage, cameras (e.g., two-dimensional (2D) and/or three-dimensional (3D) cameras), lane markers, streetlights, parking meters, etc. In some embodiments, V2I device 110 is configured to communicate directly with vehicles 102. Additionally, or alternatively, in some embodiments V2I device 110 is configured to communicate with vehicles 102, remote AV system 114, and/or fleet management system 116 via V2I system 118. In some embodiments, V2I device 110 is configured to communicate with V2I system 118 via network 112.

Network 112 includes one or more wired and/or wireless networks. In an example, network 112 includes a cellular network (e.g., a long term evolution (LTE) network, a third generation (3G) network, a fourth generation (4G) network, a fifth generation (5G) network, a code division multiple access (CDMA) network, etc.), a public land mobile network (PLMN), a local area network (LAN), a wide area network (WAN), a metropolitan area network (MAN), a telephone network (e.g., the public switched telephone network (PSTN), a private network, an ad hoc network, an intranet, the Internet, a fiber optic-based network, a cloud computing network, etc., a combination of some or all of these networks, and/or the like.

Remote AV system 114 includes at least one device configured to be in communication with vehicles 102, V2I device 110, network 112, fleet management system 116, and/or V2I system 118 via network 112. In an example, remote AV system 114 includes a server, a group of servers, and/or other like devices. In some embodiments, remote AV system 114 is co-located with the fleet management system 116. In some embodiments, remote AV system 114 is involved in the installation of some or all of the components of a vehicle, including an autonomous system, an autonomous vehicle compute, software implemented by an autonomous vehicle compute, and/or the like. In some embodiments, remote AV system 114 maintains (e.g., updates and/or replaces) such components and/or software during the lifetime of the vehicle.

Fleet management system 116 includes at least one device configured to be in communication with vehicles 102, V2I device 110, remote AV system 114, and/or V2I infrastructure system 118. In an example, fleet management system 116 includes a server, a group of servers, and/or other like devices. In some embodiments, fleet management system 116 is associated with a ridesharing company (e.g., an organization that controls operation of multiple vehicles (e.g., vehicles that include autonomous systems and/or vehicles that do not include autonomous systems) and/or the like).

In some embodiments, V2I system 118 includes at least one device configured to be in communication with vehicles 102, V2I device 110, remote AV system 114, and/or fleet management system 116 via network 112. In some examples, V2I system 118 is configured to be in communication with V2I device 110 via a connection different from network 112. In some embodiments, V2I system 118 includes a server, a group of servers, and/or other like devices. In some embodiments, V2I system 118 is associated with a municipality or a private institution (e.g., a private institution that maintains V2I device 110 and/or the like).

The number and arrangement of elements illustrated in FIG. 1 are provided as an example. There can be additional elements, fewer elements, different elements, and/or differently arranged elements, than those illustrated in FIG. 1. Additionally, or alternatively, at least one element of environment 100 can perform one or more functions described as being performed by at least one different element of FIG. 1. Additionally, or alternatively, at least one set of elements of environment 100 can perform one or more functions described as being performed by at least one different set of elements of environment 100.

Referring now to FIG. 2, vehicle 200 (which may be the same as, or similar to vehicles 102 of FIG. 1) includes or is associated with autonomous system 202, powertrain control system 204, steering control system 206, and brake system 208. In some embodiments, vehicle 200 is the same as or similar to vehicle 102 (see FIG. 1). In some embodiments, autonomous system 202 is configured to confer vehicle 200 autonomous driving capability (e.g., implement at least one driving automation or maneuver-based function, feature, device, and/or the like) that enable vehicle 200 to be partially or fully operated without human intervention including, without limitation, fully autonomous vehicles (e.g., vehicles that forego reliance on human intervention such as Level 5 ADS-operated vehicles), highly autonomous vehicles (e.g., vehicles that forego reliance on human intervention in certain situations such as Level 4 ADS-operated vehicles), conditional autonomous vehicles (e.g., vehicles that forego reliance on human intervention in limited situations such as Level 3 ADS-operated vehicles) and/or the like. In one embodiment, autonomous system 202 includes operational or tactical functionality required to operate vehicle 200 in on-road traffic and perform part or all of Dynamic Driving Task (DDT) on a sustained basis. In another embodiment, autonomous system 202 includes an Advanced Driver Assistance System (ADAS) that includes driver support features. Autonomous system 202 supports various levels of driving automation, ranging from no driving automation (e.g., Level 0) to full driving automation (e.g., Level 5). For a detailed description of fully autonomous vehicles and highly autonomous vehicles, reference may be made to SAE International's standard J3016: Taxonomy and Definitions for Terms Related to On-Road Motor Vehicle Automated Driving Systems, which is incorporated by reference in its entirety. In some embodiments, vehicle 200 is associated with an autonomous fleet manager and/or a ridesharing company.

Autonomous system 202 includes a sensor suite that includes one or more devices such as cameras 202a, LiDAR sensors 202b, radar sensors 202c, and microphones 202d. In some embodiments, autonomous system 202 can include more or fewer devices and/or different devices (e.g., ultrasonic sensors, inertial sensors, GPS receivers (discussed below), odometry sensors that generate data associated with an indication of a distance that vehicle 200 has traveled, and/or the like). In some embodiments, autonomous system 202 uses the one or more devices included in autonomous system 202 to generate data associated with environment 100, described herein. The data generated by the one or more devices of autonomous system 202 can be used by one or more systems described herein to observe the environment (e.g., environment 100) in which vehicle 200 is located. In some embodiments, autonomous system 202 includes communication device 202e, autonomous vehicle compute 202f, drive-by-wire (DBW) system 202h, and safety controller 202g.

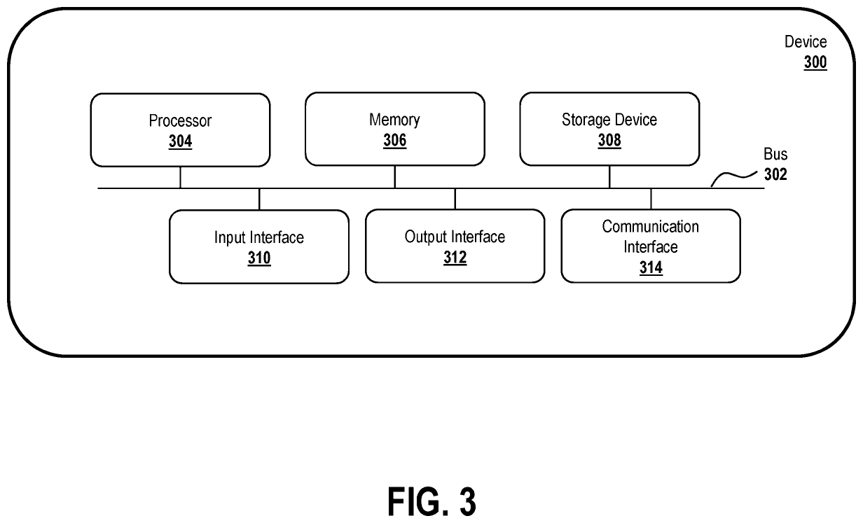

Cameras 202a include at least one device configured to be in communication with communication device 202e, autonomous vehicle compute 202f, and/or safety controller 202g via a bus (e.g., a bus that is the same as or similar to bus 302 of FIG. 3). Cameras 202a include at least one camera (e.g., a digital camera using a light sensor such as a Charge-Coupled Device (CCD), a thermal camera, an infrared (IR) camera, an event camera, and/or the like) to capture images including physical objects (e.g., cars, buses, curbs, people, and/or the like). In some embodiments, camera 202a generates camera data as output. In some examples, camera 202a generates camera data that includes image data associated with an image. In this example, the image data may specify at least one parameter (e.g., image characteristics such as exposure, brightness, etc., an image timestamp, and/or the like) corresponding to the image. In such an example, the image may be in a format (e.g., RAW, JPEG, PNG, and/or the like). In some embodiments, camera 202a includes a plurality of independent cameras configured on (e.g., positioned on) a vehicle to capture images for the purpose of stereopsis (stereo vision). In some examples, camera 202a includes a plurality of cameras that generate image data and transmit the image data to autonomous vehicle compute 202f and/or a fleet management system (e.g., a fleet management system that is the same as or similar to fleet management system 116 of FIG. 1). In such an example, autonomous vehicle compute 202f determines depth to one or more objects in a field of view of at least two cameras of the plurality of cameras based on the image data from the at least two cameras. In some embodiments, cameras 202a is configured to capture images of objects within a distance from cameras 202a (e.g., up to 100 meters, up to a kilometer, and/or the like). Accordingly, cameras 202a include features such as sensors and lenses that are optimized for perceiving objects that are at one or more distances from cameras 202a.

In an embodiment, camera 202a includes at least one camera configured to capture one or more images associated with one or more traffic lights, street signs and/or other physical objects that provide visual navigation information. In some embodiments, camera 202a generates traffic light data associated with one or more images. In some examples, camera 202a generates TLD (Traffic Light Detection) data associated with one or more images that include a format (e.g., RAW, JPEG, PNG, and/or the like). In some embodiments, camera 202a that generates TLD data differs from other systems described herein incorporating cameras in that camera 202a can include one or more cameras with a wide field of view (e.g., a wide-angle lens, a fish-eye lens, a lens having a viewing angle of approximately 120 degrees or more, and/or the like) to generate images about as many physical objects as possible.

Light Detection and Ranging (LiDAR) sensors 202b include at least one device configured to be in communication with communication device 202e, autonomous vehicle compute 202f, and/or safety controller 202g via a bus (e.g., a bus that is the same as or similar to bus 302 of FIG. 3). LiDAR sensors 202b include a system configured to transmit light from a light emitter (e.g., a laser transmitter). Light emitted by LiDAR sensors 202b include light (e.g., infrared light and/or the like) that is outside of the visible spectrum. In some embodiments, during operation, light emitted by LiDAR sensors 202b encounters a physical object (e.g., a vehicle) and is reflected back to LiDAR sensors 202b. In some embodiments, the light emitted by LiDAR sensors 202b does not penetrate the physical objects that the light encounters. LiDAR sensors 202b also include at least one light detector which detects the light that was emitted from the light emitter after the light encounters a physical object. In some embodiments, at least one data processing system associated with LiDAR sensors 202b generates an image (e.g., a point cloud, a combined point cloud, and/or the like) representing the objects included in a field of view of LiDAR sensors 202b. In some examples, the at least one data processing system associated with LiDAR sensor 202b generates an image that represents the boundaries of a physical object, the surfaces (e.g., the topology of the surfaces) of the physical object, and/or the like. In such an example, the image is used to determine the boundaries of physical objects in the field of view of LiDAR sensors 202b.

Radio Detection and Ranging (radar) sensors 202c include at least one device configured to be in communication with communication device 202e, autonomous vehicle compute 202f, and/or safety controller 202g via a bus (e.g., a bus that is the same as or similar to bus 302 of FIG. 3). Radar sensors 202c include a system configured to transmit radio waves (either pulsed or continuously). The radio waves transmitted by radar sensors 202c include radio waves that are within a predetermined spectrum. In some embodiments, during operation, radio waves transmitted by radar sensors 202c encounter a physical object and are reflected back to radar sensors 202c. In some embodiments, the radio waves transmitted by radar sensors 202c are not reflected by some objects. In some embodiments, at least one data processing system associated with radar sensors 202c generates signals representing the objects included in a field of view of radar sensors 202c. For example, the at least one data processing system associated with radar sensor 202c generates an image that represents the boundaries of a physical object, the surfaces (e.g., the topology of the surfaces) of the physical object, and/or the like. In some examples, the image is used to determine the boundaries of physical objects in the field of view of radar sensors 202c.

Microphones 202d includes at least one device configured to be in communication with communication device 202e, autonomous vehicle compute 202f, and/or safety controller 202g via a bus (e.g., a bus that is the same as or similar to bus 302 of FIG. 3). Microphones 202d include one or more microphones (e.g., array microphones, external microphones, and/or the like) that capture audio signals and generate data associated with (e.g., representing) the audio signals. In some examples, microphones 202d include transducer devices and/or like devices. In some embodiments, one or more systems described herein can receive the data generated by microphones 202d and determine a position of an object relative to vehicle 200 (e.g., a distance and/or the like) based on the audio signals associated with the data.

Communication device 202e includes at least one device configured to be in communication with cameras 202a, LiDAR sensors 202b, radar sensors 202c, microphones 202d, autonomous vehicle compute 202f, safety controller 202g, and/or DBW (Drive-By-Wire) system 202h. For example, communication device 202e may include a device that is the same as or similar to communication interface 314 of FIG. 3. In some embodiments, communication device 202e includes a vehicle-to-vehicle (V2V) communication device (e.g., a device that enables wireless communication of data between vehicles).

Autonomous vehicle compute 202f include at least one device configured to be in communication with cameras 202a, LiDAR sensors 202b, radar sensors 202c, microphones 202d, communication device 202e, safety controller 202g, and/or DBW system 202h. In some examples, autonomous vehicle compute 202f includes a device such as a client device, a mobile device (e.g., a cellular telephone, a tablet, and/or the like), a server (e.g., a computing device including one or more central processing units, graphical processing units, and/or the like), and/or the like. In some embodiments, autonomous vehicle compute 202f is the same as or similar to autonomous vehicle compute 400, described herein. Additionally, or alternatively, in some embodiments autonomous vehicle compute 202f is configured to be in communication with an autonomous vehicle system (e.g., an autonomous vehicle system that is the same as or similar to remote AV system 114 of FIG. 1), a fleet management system (e.g., a fleet management system that is the same as or similar to fleet management system 116 of FIG. 1), a V2I device (e.g., a V2I device that is the same as or similar to V2I device 110 of FIG. 1), and/or a V2I system (e.g., a V2I system that is the same as or similar to V2I system 118 of FIG. 1).

Safety controller 202g includes at least one device configured to be in communication with cameras 202a, LiDAR sensors 202b, radar sensors 202c, microphones 202d, communication device 202e, autonomous vehicle computer 202f, and/or DBW system 202h. In some examples, safety controller 202g includes one or more controllers (electrical controllers, electromechanical controllers, and/or the like) that are configured to generate and/or transmit control signals to operate one or more devices of vehicle 200 (e.g., powertrain control system 204, steering control system 206, brake system 208, and/or the like). In some embodiments, safety controller 202g is configured to generate control signals that take precedence over (e.g., overrides) control signals generated and/or transmitted by autonomous vehicle compute 202f.

DBW system 202h includes at least one device configured to be in communication with communication device 202e and/or autonomous vehicle compute 202f. In some examples, DBW system 202h includes one or more controllers (e.g., electrical controllers, electromechanical controllers, and/or the like) that are configured to generate and/or transmit control signals to operate one or more devices of vehicle 200 (e.g., powertrain control system 204, steering control system 206, brake system 208, and/or the like). Additionally, or alternatively, the one or more controllers of DBW system 202h are configured to generate and/or transmit control signals to operate at least one different device (e.g., a turn signal, headlights, door locks, windshield wipers, and/or the like) of vehicle 200.

Powertrain control system 204 includes at least one device configured to be in communication with DBW system 202h. In some examples, powertrain control system 204 includes at least one controller, actuator, and/or the like. In some embodiments, powertrain control system 204 receives control signals from DBW system 202h and powertrain control system 204 causes vehicle 200 to make longitudinal vehicle motion, such as start moving forward, stop moving forward, start moving backward, stop moving backward, accelerate in a direction, decelerate in a direction or to make lateral vehicle motion such as performing a left turn, performing a right turn, and/or the like. In an example, powertrain control system 204 causes the energy (e.g., fuel, electricity, and/or the like) provided to a motor of the vehicle to increase, remain the same, or decrease, thereby causing at least one wheel of vehicle 200 to rotate or not rotate.

Steering control system 206 includes at least one device configured to rotate one or more wheels of vehicle 200. In some examples, steering control system 206 includes at least one controller, actuator, and/or the like. In some embodiments, steering control system 206 causes the front two wheels and/or the rear two wheels of vehicle 200 to rotate to the left or right to cause vehicle 200 to turn to the left or right. In other words, steering control system 206 causes activities necessary for the regulation of the y-axis component of vehicle motion.

Brake system 208 includes at least one device configured to actuate one or more brakes to cause vehicle 200 to reduce speed and/or remain stationary. In some examples, brake system 208 includes at least one controller and/or actuator that is configured to cause one or more calipers associated with one or more wheels of vehicle 200 to close on a corresponding rotor of vehicle 200. Additionally, or alternatively, in some examples brake system 208 includes an automatic emergency braking (AEB) system, a regenerative braking system, and/or the like.

In some embodiments, vehicle 200 includes at least one platform sensor (not explicitly illustrated) that measures or infers properties of a state or a condition of vehicle 200. In some examples, vehicle 200 includes platform sensors such as a global positioning system (GPS) receiver, an inertial measurement unit (IMU), a wheel speed sensor, a wheel brake pressure sensor, a wheel torque sensor, an engine torque sensor, a steering angle sensor, and/or the like. Although brake system 208 is illustrated to be located in the near side of vehicle 200 in FIG. 2, brake system 208 may be located anywhere in vehicle 200.

Referring now to FIG. 3, illustrated is a schematic diagram of a device 300. As illustrated, device 300 includes processor 304, memory 306, storage component 308, input interface 310, output interface 312, communication interface 314, and bus 302. In some embodiments, device 300 corresponds to at least one device of vehicles 102 (e.g., at least one device of a system of vehicles 102) and/or one or more devices of network 112 (e.g., one or more devices of a system of network 112). In some embodiments, one or more devices of vehicles 102 (e.g., one or more devices of a system of vehicles 102) and/or one or more devices of network 112 (e.g., one or more devices of a system of network 112) include at least one device 300 and/or at least one component of device 300. As shown in FIG. 3, device 300 includes bus 302, processor 304, memory 306, storage component 308, input interface 310, output interface 312, and communication interface 314.

Bus 302 includes a component that permits communication among the components of device 300. In some cases, processor 304 includes a processor (e.g., a central processing unit (CPU), a graphics processing unit (GPU), an accelerated processing unit (APU), and/or the like), a microphone, a digital signal processor (DSP), and/or any processing component (e.g., a field-programmable gate array (FPGA), an application specific integrated circuit (ASIC), and/or the like) that can be programmed to perform at least one function. Memory 306 includes random access memory (RAM), read-only memory (ROM), and/or another type of dynamic and/or static storage device (e.g., flash memory, magnetic memory, optical memory, and/or the like) that stores data and/or instructions for use by processor 304.

Storage component 308 stores data and/or software related to the operation and use of device 300. In some examples, storage component 308 includes a hard disk (e.g., a magnetic disk, an optical disk, a magneto-optic disk, a solid state disk, and/or the like), a compact disc (CD), a digital versatile disc (DVD), a floppy disk, a cartridge, a magnetic tape, a CD-ROM, RAM, PROM, EPROM, FLASH-EPROM, NV-RAM, and/or another type of computer readable medium, along with a corresponding drive.

Input interface 310 includes a component that permits device 300 to receive information, such as via user input (e.g., a touchscreen display, a keyboard, a keypad, a mouse, a button, a switch, a microphone, a camera, and/or the like). Additionally or alternatively, in some embodiments input interface 310 includes a sensor that senses information (e.g., a global positioning system (GPS) receiver, an accelerometer, a gyroscope, an actuator, and/or the like). Output interface 312 includes a component that provides output information from device 300 (e.g., a display, a speaker, one or more light-emitting diodes (LEDs), and/or the like).

In some embodiments, communication interface 314 includes a transceiver-like component (e.g., a transceiver, a separate receiver and transmitter, and/or the like) that permits device 300 to communicate with other devices via a wired connection, a wireless connection, or a combination of wired and wireless connections. In some examples, communication interface 314 permits device 300 to receive information from another device and/or provide information to another device. In some examples, communication interface 314 includes an Ethernet interface, an optical interface, a coaxial interface, an infrared interface, a radio frequency (RF) interface, a universal serial bus (USB) interface, a Wi-Fi® interface, a cellular network interface, and/or the like.

In some embodiments, device 300 performs one or more processes described herein. Device 300 performs these processes based on processor 304 executing software instructions stored by a computer-readable medium, such as memory 305 and/or storage component 308. A computer-readable medium (e.g., a non-transitory computer readable medium) is defined herein as a non-transitory memory device. A non-transitory memory device includes memory space located inside a single physical storage device or memory space spread across multiple physical storage devices.

In some embodiments, software instructions are read into memory 306 and/or storage component 308 from another computer-readable medium or from another device via communication interface 314. When executed, software instructions stored in memory 306 and/or storage component 308 cause processor 304 to perform one or more processes described herein. Additionally or alternatively, hardwired circuitry is used in place of or in combination with software instructions to perform one or more processes described herein. Thus, embodiments described herein are not limited to any specific combination of hardware circuitry and software unless explicitly stated otherwise.

Memory 306 and/or storage component 308 includes data storage or at least one data structure (e.g., a database and/or the like). Device 300 is capable of receiving information from, storing information in, communicating information to, or searching information stored in the data storage or the at least one data structure in memory 306 or storage component 308. In some examples, the information includes network data, input data, output data, or any combination thereof.

In some embodiments, device 300 is configured to execute software instructions that are either stored in memory 306 and/or in the memory of another device (e.g., another device that is the same as or similar to device 300). As used herein, the term “module” refers to at least one instruction stored in memory 306 and/or in the memory of another device that, when executed by processor 304 and/or by a processor of another device (e.g., another device that is the same as or similar to device 300) cause device 300 (e.g., at least one component of device 300) to perform one or more processes described herein. In some embodiments, a module is implemented in software, firmware, hardware, and/or the like.

The number and arrangement of components illustrated in FIG. 3 are provided as an example. In some embodiments, device 300 can include additional components, fewer components, different components, or differently arranged components than those illustrated in FIG. 3. Additionally or alternatively, a set of components (e.g., one or more components) of device 300 can perform one or more functions described as being performed by another component or another set of components of device 300.

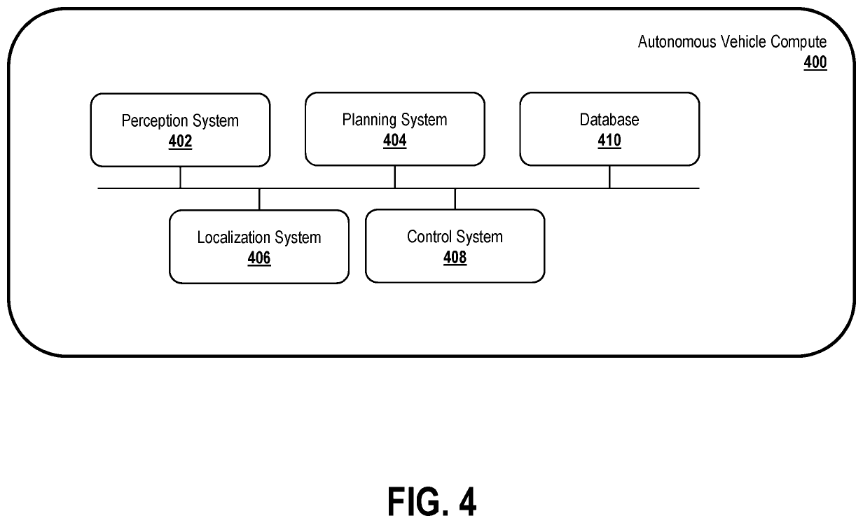

Referring now to FIG. 4, illustrated is an example block diagram of an autonomous vehicle compute 400 (sometimes referred to as an “AV stack”). As illustrated, autonomous vehicle compute 400 includes perception system 402 (sometimes referred to as a perception module), planning system 404 (sometimes referred to as a planning module), localization system 406 (sometimes referred to as a localization module), control system 408 (sometimes referred to as a control module), and database 410. In some embodiments, perception system 402, planning system 404, localization system 406, control system 408, and database 410 are included and/or implemented in an autonomous navigation system of a vehicle (e.g., autonomous vehicle compute 202f of vehicle 200). Additionally, or alternatively, in some embodiments perception system 402, planning system 404, localization system 406, control system 408, and database 410 are included in one or more standalone systems (e.g., one or more systems that are the same as or similar to autonomous vehicle compute 400 and/or the like). In some examples, perception system 402, planning system 404, localization system 406, control system 408, and database 410 are included in one or more standalone systems that are located in a vehicle and/or at least one remote system as described herein. In some embodiments, any and/or all of the systems included in autonomous vehicle compute 400 are implemented in software (e.g., in software instructions stored in memory), computer hardware (e.g., by microprocessors, microcontrollers, application-specific integrated circuits (ASICs), Field Programmable Gate Arrays (FPGAs), and/or the like), or combinations of computer software and computer hardware. It will also be understood that, in some embodiments, autonomous vehicle compute 400 is configured to be in communication with a remote system (e.g., an autonomous vehicle system that is the same as or similar to remote AV system 114, a fleet management system 116 that is the same as or similar to fleet management system 116, a V2I system that is the same as or similar to V2I system 118, and/or the like).

In some embodiments, perception system 402 receives data associated with at least one physical object (e.g., data that is used by perception system 402 to detect the at least one physical object) in an environment and classifies the at least one physical object. In some examples, perception system 402 receives image data captured by at least one camera (e.g., cameras 202a), the image associated with (e.g., representing) one or more physical objects within a field of view of the at least one camera. In such an example, perception system 402 classifies at least one physical object based on one or more groupings of physical objects (e.g., bicycles, vehicles, traffic signs, pedestrians, and/or the like). In some embodiments, perception system 402 transmits data associated with the classification of the physical objects to planning system 404 based on perception system 402 classifying the physical objects.

In some embodiments, planning system 404 receives data associated with a destination and generates data associated with at least one route (e.g., routes 106) along which a vehicle (e.g., vehicles 102) can travel along toward a destination. In some embodiments, planning system 404 periodically or continuously receives data from perception system 402 (e.g., data associated with the classification of physical objects, described above) and planning system 404 updates the at least one trajectory or generates at least one different trajectory based on the data generated by perception system 402. In other words, planning system 404 may perform tactical function-related tasks that are required to operate vehicle 102 in on-road traffic. Tactical efforts involve maneuvering the vehicle in traffic during a trip, including but not limited to deciding whether and when to overtake another vehicle, change lanes, or selecting an appropriate speed, acceleration, deacceleration, etc. In some embodiments, planning system 404 receives data associated with an updated position of a vehicle (e.g., vehicles 102) from localization system 406 and planning system 404 updates the at least one trajectory or generates at least one different trajectory based on the data generated by localization system 406.

In some embodiments, localization system 406 receives data associated with (e.g., representing) a location of a vehicle (e.g., vehicles 102) in an area. In some examples, localization system 406 receives LiDAR data associated with at least one point cloud generated by at least one LiDAR sensor (e.g., LiDAR sensors 202b). In certain examples, localization system 406 receives data associated with at least one point cloud from multiple LiDAR sensors and localization system 406 generates a combined point cloud based on each of the point clouds. In these examples, localization system 406 compares the at least one point cloud or the combined point cloud to two-dimensional (2D) and/or a three-dimensional (3D) map of the area stored in database 410. Localization system 406 then determines the position of the vehicle in the area based on localization system 406 comparing the at least one point cloud or the combined point cloud to the map. In some embodiments, the map includes a combined point cloud of the area generated prior to navigation of the vehicle. In some embodiments, maps include, without limitation, high-precision maps of the roadway geometric properties, maps describing road network connectivity properties, maps describing roadway physical properties (such as traffic speed, traffic volume, the number of vehicular and cyclist traffic lanes, lane width, lane traffic directions, or lane marker types and locations, or combinations thereof), and maps describing the spatial locations of road features such as crosswalks, traffic signs or other travel signals of various types. In some embodiments, the map is generated in real-time based on the data received by the perception system.

In another example, localization system 406 receives Global Navigation Satellite System (GNSS) data generated by a global positioning system (GPS) receiver. In some examples, localization system 406 receives GNSS data associated with the location of the vehicle in the area and localization system 406 determines a latitude and longitude of the vehicle in the area. In such an example, localization system 406 determines the position of the vehicle in the area based on the latitude and longitude of the vehicle. In some embodiments, localization system 406 generates data associated with the position of the vehicle. In some examples, localization system 406 generates data associated with the position of the vehicle based on localization system 406 determining the position of the vehicle. In such an example, the data associated with the position of the vehicle includes data associated with one or more semantic properties corresponding to the position of the vehicle.

In some embodiments, control system 408 receives data associated with at least one trajectory from planning system 404 and control system 408 controls operation of the vehicle. In some examples, control system 408 receives data associated with at least one trajectory from planning system 404 and control system 408 controls operation of the vehicle by generating and transmitting control signals to cause a powertrain control system (e.g., DBW system 202h, powertrain control system 204, and/or the like), a steering control system (e.g., steering control system 206), and/or a brake system (e.g., brake system 208) to operate. For example, control system 408 is configured to perform operational functions such as a lateral vehicle motion control or a longitudinal vehicle motion control. The lateral vehicle motion control causes activities necessary for the regulation of the y-axis component of vehicle motion. The longitudinal vehicle motion control causes activities necessary for the regulation of the x-axis component of vehicle motion. In an example, where a trajectory includes a left turn, control system 408 transmits a control signal to cause steering control system 206 to adjust a steering angle of vehicle 200, thereby causing vehicle 200 to turn left. Additionally, or alternatively, control system 408 generates and transmits control signals to cause other devices (e.g., headlights, turn signal, door locks, windshield wipers, and/or the like) of vehicle 200 to change states.

In some embodiments, perception system 402, planning system 404, localization system 406, and/or control system 408 implement at least one machine learning model (e.g., at least one multilayer perceptron (MLP), at least one convolutional neural network (CNN), at least one recurrent neural network (RNN), at least one autoencoder, at least one transformer, and/or the like). In some examples, perception system 402, planning system 404, localization system 406, and/or control system 408 implement at least one machine learning model alone or in combination with one or more of the above-noted systems. In some examples, perception system 402, planning system 404, localization system 406, and/or control system 408 implement at least one machine learning model as part of a pipeline (e.g., a pipeline for identifying one or more objects located in an environment and/or the like).

Database 410 stores data that is transmitted to, received from, and/or updated by perception system 402, planning system 404, localization system 406 and/or control system 408. In some examples, database 410 includes a storage component (e.g., a storage component that is the same as or similar to storage component 308 of FIG. 3) that stores data and/or software related to the operation and uses at least one system of autonomous vehicle compute 400. In some embodiments, database 410 stores data associated with 2D and/or 3D maps of at least one area. In some examples, database 410 stores data associated with 2D and/or 3D maps of a portion of a city, multiple portions of multiple cities, multiple cities, a county, a state, a State (e.g., a country), and/or the like). In such an example, a vehicle (e.g., a vehicle that is the same as or similar to vehicles 102 and/or vehicle 200) can drive along one or more drivable regions (e.g., single-lane roads, multi-lane roads, highways, back roads, off road trails, and/or the like) and cause at least one LiDAR sensor (e.g., a LIDAR sensor that is the same as or similar to LiDAR sensors 202b) to generate data associated with an image representing the objects included in a field of view of the at least one LiDAR sensor.

In some embodiments, database 410 can be implemented across a plurality of devices. In some examples, database 410 is included in a vehicle (e.g., a vehicle that is the same as or similar to vehicles 102 and/or vehicle 200), an autonomous vehicle system (e.g., an autonomous vehicle system that is the same as or similar to remote AV system 114, a fleet management system (e.g., a fleet management system that is the same as or similar to fleet management system 116 of FIG. 1, a V2I system (e.g., a V2I system that is the same as or similar to V2I system 118 of FIG. 1) and/or the like.

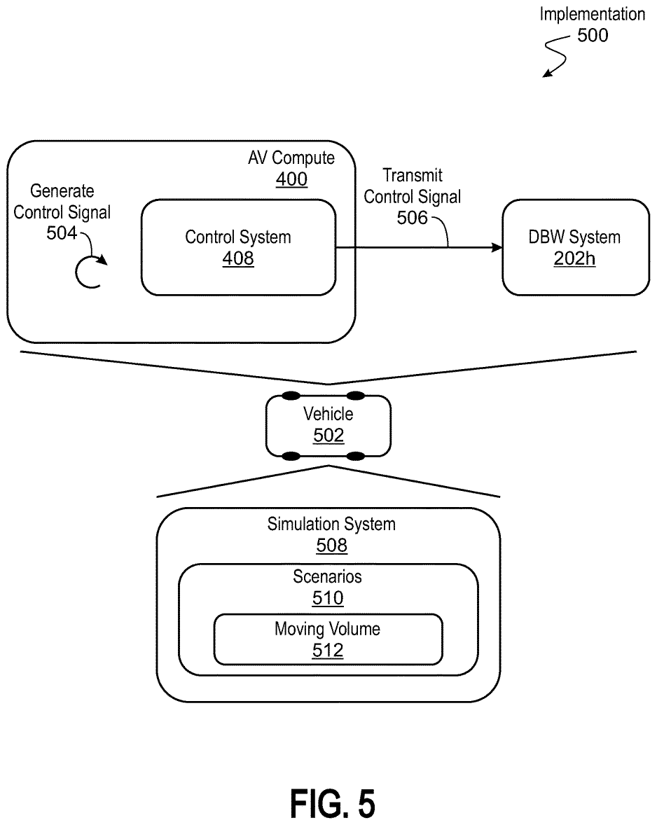

Referring now to FIG. 5, illustrated is a diagram of an implementation 500 of generating agents relative to a simulated autonomous vehicle. In some embodiments, implementation 500 represents a simulation that mimics an environment (e.g., environment 100 of FIG. 1), including vehicles that operate using autonomous systems and vehicles that do not operate using autonomous systems. In examples, simulation refers to imitating the environment such that an autonomous system (e.g., autonomous system 202 of FIG. 2) behaves as though it is implementing at least one driving automation or maneuver-based function, feature, device, and/or the like that enable a vehicle to be partially or fully operated without human intervention in the real-world. The behavior and responses of the autonomous system are used to evaluate performance of the autonomous system in the real world.

In the implementation 500, a simulated vehicle 502 mimics functions of an AV compute 400 and DBW system 202h. For example, the simulated vehicle 502 imitates functionality of physical vehicles, such as vehicles 102 of FIG. 1, vehicle 200 of FIG. 2. In some embodiments, AV compute 400 is the same as or similar to AV compute 400 of FIG. 4, the control system 408 is the same as or similar to the control system 408 of FIG. 4, and DBW system 202h is the same as or similar to DBW system 202h of FIG. 2. As shown in FIG. 5, the simulated vehicle 502 generates control signals (504). A control system 408 controls operation of the simulated vehicle 502 by generating and transmitting control signals (506) to cause a DBW system 202h to operate.

In the example of FIG. 5, inputs to the AV compute 400 are simulated in scenarios 510 generated by a simulation system 508, and the outputs (e.g., control signal 506) of the AV compute 400 and DBW system 202h are obtained to evaluate the performance of the AV compute 400, including behavior of the simulated vehicle 502 in response to the simulated inputs from the simulation system 508. In some embodiments, outputs obtained to evaluate performance of the simulated vehicle 502 include, for example, data output by subsystems (e.g., perception system 402, planning system 404, localization system 406, control system 408, and database 410 of FIG. 4), sensors (cameras 202a, LiDAR sensors 202b, radar sensors 202c, microphones 202d of FIG. 2), and devices (e.g., communication device 202e, safety controller 202g, and/or DBW system 202h of FIG. 2) that process the data to enable an autonomous vehicle to recognize, understand, and make decisions within the environment.

A scenario of the scenarios 510 includes time series data that is representative of a simulated environment. In examples, a simulation imitates a real-world environment by inputting the time series data representing the environment into an autonomous system, which may be the same as, or similar to, the autonomous system 202 of FIG. 2. In examples, hardware of the autonomous system, software of the autonomous system, or any combinations thereof receive the time series data, and generate outputs in response to the inputs. The time series data includes, for example, sensor data (e.g., data representing point clouds, optical camera images, infrared camera images, radar images, and/or the like collected at one or more points in time), vehicle dynamics, simulated agents (e.g., simulated agent models), data corresponding to environmental conditions, and the like. Additionally, in examples, the time series data includes perception data, sensor data, vehicle dynamics, environmental data, and the like. The time series data is collectively referred to as a scenario, and the scenario is input to the autonomous system. The simulation system 508 obtains output from the autonomous system, where the output represents the behavior or response of the autonomous system to the scenario. The simulation system 508 dynamically and iteratively updates the scenario according to the response of the autonomous system. In examples, the scenario is referred to as including frames of data, where a frame is a set of time series data at a specified point in time. The scenario is simulated by generating frames of data that are input to the autonomous system, and the response (e.g., outputs) of the autonomous system to scenario informs subsequent frames of data for an interval of time.

In some embodiments, the scenario includes one or more simulated agents generated within a moving volume 512. The moving volume 512 is collocated with the simulated vehicle 502, and the simulated vehicle 502 is located at the center of the moving volume. In some embodiments, the size and location of the volume evolves as the simulated vehicle navigates through an environment. Random traffic generation occurs within the moving volume, and refers to the generation of traffic as the simulated vehicle 502 moves through the scenario. In examples, traffic includes simulated agents that are populated around the simulated vehicle 502. Simulated agents are, for example, participants in the simulated environment, such as objects 104a-104n of FIG. 1. Accordingly, simulated agents include vehicles, pedestrians, cyclists, structures (e.g., a building, a sign, a fire hydrant, road block, etc.), animals, debris, and/or the like. As the simulated vehicle 502 and moving volume 512 move through a simulated environment, simulated agents are spawned, despawned, and act to achieve a goal. Spawning refers to the generation of data in the simulated environment representing an simulated agent. Despawning refers to ceasing the generation of data in the simulated environment representing a respective simulated agent. In examples, a goal is the end toward which efforts are directed for a respective simulated agent. For example, a goal is a destination, where an simulated agent in a simulated environment acts to arrive at the destination. In examples, goals are assigned to simulated agents based on a context (e.g., time of day, environmental conditions) of the simulation. For example, based on the time of day, simulated agents are assigned a goal of traveling towards open businesses in the simulated environment. In examples, environmental conditions include rain, snow, or other inclement weather. Simulated agents are assigned a goal that includes avoiding impacts of the environmental conditions during the simulation. For example, simulated agents can travel to a goal location while using features of the environment to avoid rain or snow. This can include, for example, traveling underneath an awning or near a building for protection from rain, snow, wind, or sun. In this example, simulated agents with protection (e.g., umbrellas, wind gear, warm jackets) can travel through areas with greater exposure to the environmental conditions.

At least one simulated agent is spawned or despawned in the simulated environment according to features of the simulated vehicle 502. For example, simulated agents are spawned relative to a speed of the simulated vehicle 502 as it moves through the simulated environment. A size and location of the moving volume 512 is updated as the vehicle navigates along a route. In some embodiments, the simulated agents are intelligent simulated agents that act according to a respective simulated agent model with distributed control. For example, the intelligent simulated agents are aware of other simulated agents and features of the environment. Features of the environment include time of day, weather conditions, location type (e.g., urban, rural, etc.), terrain, landscaping, and the like. The intelligent simulated agents make independent decisions to reach a goal in view of other objects and features of the environment according to a respective simulated agent model. In some embodiments, the simulated agents act according to centralized control of a hivemind controller. For examples, the simulated agents are drones under the control of the hivemind controller. The hivemind controller coordinates the spawning and despawning of simulated agents and the goals associated with the simulated agents. The hivemind controller ensures that the simulated agents are aware of and respond to other simulated agents and features of the environment. The controller guides the simulated agents and makes decisions for each simulated agent to reach a goal destination for each simulated agent.

In some embodiments, the generation of traffic within the moving volume enables simulations that are extensive in duration while consuming fewer computational resources when compared to simulations without moving volumes of the same duration. Simulations without the generation of traffic within moving volumes simulate simulated agents in the environment for a region traversed by a simulated vehicle, which is computationally intensive. For example, in a scenario that includes an hour long route through an environment, the present techniques spawn and despawn simulated agents in a moving volume along the hour-long route. By contrast, without a moving volume, simulated agents are simulated for a stationary region of the environment including the entire hour long route in a computationally intensive process.

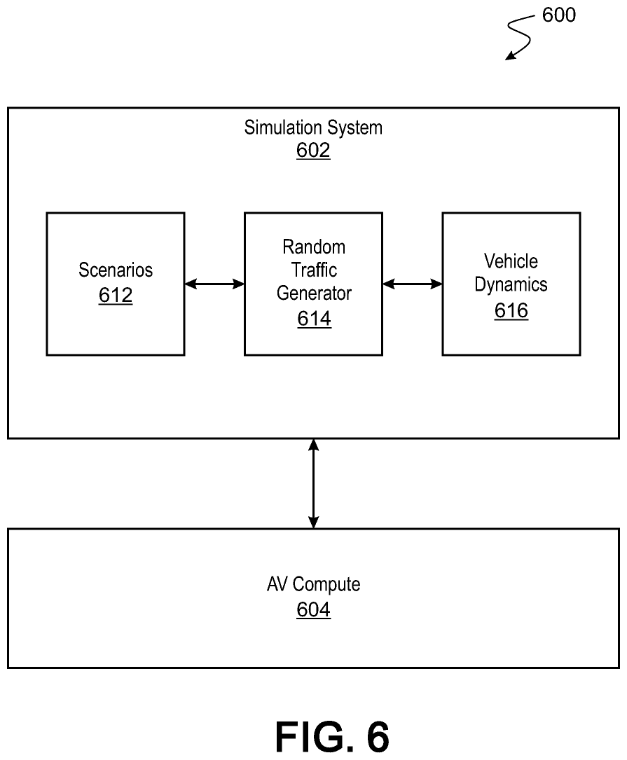

FIG. 6 shows a testing infrastructure 600. The testing infrastructure 600 enables random traffic generation. The testing infrastructure 600 is implemented at, for example, a device 300 of FIG. 3. The testing infrastructure 600 enables testing, validation, and verification of autonomous systems. The autonomous systems are, for example, the same as or similar to autonomous system 202 of FIG. 2. Additionally, in examples, the autonomous systems are configured to confer autonomous driving capability on an autonomous vehicle, such as vehicle 200 of FIG. 2. Moreover, in some examples, the testing infrastructure enables testing, validation, and verification of components of the autonomous system, such as cameras 202a, LiDAR sensors 202b, radar sensors 202c, microphones 202d, communication device 202e, autonomous vehicle compute 202f, drive-by-wire (DBW) system 202h, or safety controller 202g of FIG. 2. For ease of description, the present techniques are described using an autonomous vehicle as associated with the autonomous system under test. However, any autonomous system can be tested according to the present techniques. In examples, testing ensures that autonomous vehicles operate in a safe and error-free manner.

The testing infrastructure 600 includes a simulation system 602 and AV compute 604. The simulation system 602 manages and executes scenarios used to test, validate, and verify performance of the AV compute 604. In examples, the AV compute 604 is the same as or similar to the AV compute 400 of the simulated vehicle 502 as described with respect to FIGS. 4 and 5. The AV compute 604 is communicatively coupled with the simulation system 602. In examples, during simulation the AV compute 604 outputs data corresponding to a driving capability (e.g., implement at least one driving automation or maneuver-based function, feature, device, and/or the like) in response to the simulated environment. The output data is obtained by the simulation system 602.

The AV compute 604 is evaluated for testing, validation, or verification by interpreting the response or behavior of the AV compute 604 to scenarios 612. In some embodiments, the scenarios 612 are the same as or similar to scenarios 510 of FIG. 5. In examples, result of the simulations of scenarios 612 are applied to update or further develop the autonomous system (e.g., AV compute 604). For example, the response or behavior of the autonomous system during a simulation is compared to an expected response or behavior of an autonomous system to a scenario. Differences between the response during simulation and the expected response of an autonomous system are evaluated to identify at least one root cause of the differences. The identified root cause is corrected by actions such as updating software, hardware, or any combination thereof associated with the autonomous system. The autonomous system is then deployed in the real world (e.g., AV compute 604 is deployed on a vehicle that operates in the real world) after meeting various standards verified via the simulation of scenarios 612. In examples, the scenarios 612 include simulated agents generated by the random traffic generator 614. The scenarios 612 are representative of a simulated environment in which a simulated autonomous vehicle operates as controlled by the AV compute 604. The scenarios 612 includes simulated data, such as simulated time series data. The simulated data is, for example, simulated inputs of one or more devices such as cameras 202a, LiDAR sensors 202b, radar sensors 202c, microphones 202d, and communication device 202e. In examples, the scenarios 612 include data provided as input to perception system 402, planning system 404, localization system 406, control system 408, and database 410 as described with respect to FIG. 4. Additionally, the simulation system 602 includes vehicle dynamics 616. In examples, vehicle dynamics 616 simulates outputs representative of vehicle dynamics. For example, vehicle dynamics 616 include simulated outputs of one or more devices such as drive-by-wire (DBW) system 202h, safety controller 202g, powertrain control system 204, steering control system 206, and brake system 208.

For ease of description, the scenarios 612, output of the random traffic generator 614, and vehicle dynamics 616 are simulated data associated with the operation of vehicle systems and provided to AV compute 604. However, in some embodiments the vehicle systems such as cameras 202a, LiDAR sensors 202b, radar sensors 202c, microphones 202d, communication device 202e, drive-by-wire (DBW) system 202h, safety controller 202g, powertrain control system 204, steering control system 206, and brake system 208 are tested, validated, or verified by providing simulated data from the simulation system 602 to the respective vehicle system.

In examples, the random traffic generator 614 randomly spawns simulated agents which creates an operational envelope that mimics real world environments. Random, unpredictable generation of traffic enables a lack of patterns or predictability similar to situations encountered in the real world. The scenarios 612 are input into an AV compute 604 to evaluate the performance of the AV compute. A response of the AV compute 604 in a simulation of a scenario is validated in view of appropriate behaviors in response to the randomly generated simulated agents.

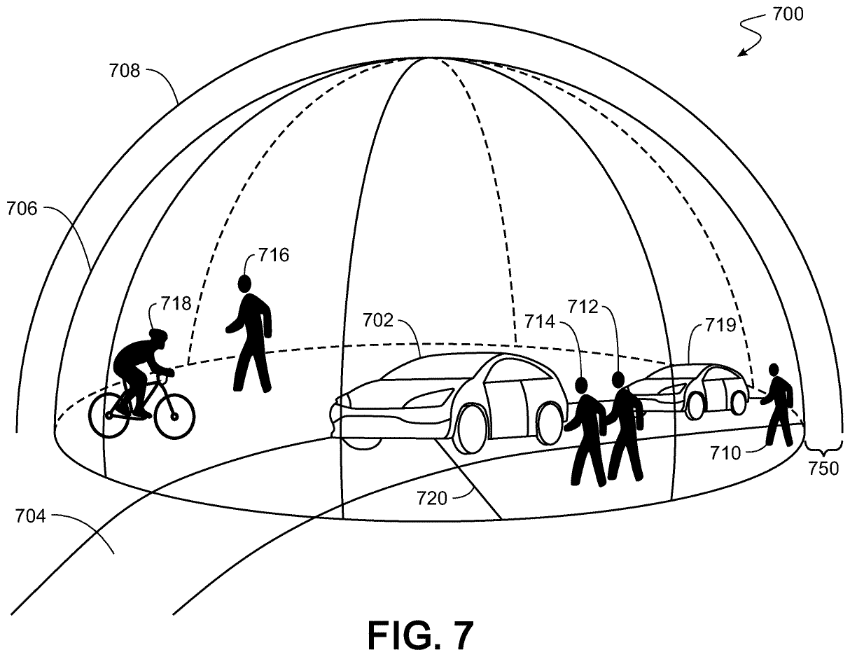

FIG. 7 shows a moving volume 700 with agents generated relative to a simulated autonomous vehicle according to the present techniques. In examples, the moving volume 700 is the moving volume 512 described with respect to FIG. 5. The moving volume 700 is implemented (e.g., completely, partially, etc.) using a simulation system that is the same as or similar to simulation system 602 of FIG. 6. In the example of FIG. 7, a simulated vehicle 702 is located at the center of the volume 700 and navigates along a route 704. Traffic is randomly generated within the volume 700. The volume 700 is defined by two layers. The first layer defines a perception area 706 of the simulated vehicle 702. The perception area 706 corresponds to the area of the environment able to be perceived by the simulated vehicle 702. In examples, the area of the environment able to be perceived by the simulated vehicle 702 is based on detection ranges associated with hardware of an autonomous vehicle, including devices such as cameras 202a, LiDAR sensors 202b, radar sensors 202c, and microphones 202d. As shown in FIG. 7, the perception area 706 of the simulated vehicle 702 is marked by a radius 720 extending from the simulated vehicle 702. In an example, the radius is 120 meters in length.

A second layer of the volume 700 defines a maximum extent area 708 as the maximum extent of the volume beyond the perception area 706. In some embodiments, the random traffic generation occurs in a region 750 of the volume 700 between the perception area 706 and maximum extent area 708. The simulated agents spawn and despawn in the region 750 of the moving volume 700 to enable a realistic entry and exit to the perception area 706. Spawning and despawning simulated agents in the region 750 prevents the sudden appearance or disappearance of simulated agents in the perception area 706 of the moving volume 700. In embodiments, the simulated agents are spawned outside of the perception area 706 of the volume but within the maximum extent area 708, and then enter into perception range (e.g., within the perception area 706) as the simulated vehicle 702 navigates along the route 704. In this manner, natural entrances to the perception area 706 imitate entrances to perception range of a vehicle in the real world.

In some embodiments, each simulation run (e.g., the execution of a scenario) is initiated using a seed value. In some embodiments, the simulated agents are initially spawned according to a seed that specifies an initial set of simulated agents. In examples, the seed is deterministic and completely specifies a spawn/despawn pattern as the simulated vehicle navigates along a route. For example, a deterministic seed can spawn a same group of simulated agents at a same cadence with the same goals each time a simulation of a scenario is executed. In examples, the simulation system randomly selects a seed to specify an initial set of simulated agents, goals associated with respective simulated agents, and the like. In examples, the randomly selected seed is deterministic and can be selected for subsequent simulations. This enables the discovery of edge cases through randomly selected seeds, and the re-testing of random simulations including the edge cases. An edge case is a scenario that occurs at unique or extreme simulation variables, simulation parameters, or any combinations thereof. Additionally, in examples a null seed is nondeterministic and randomly selects the simulated agents to spawn as the vehicle navigates through the environment across multiple executions of a simulation.

In the example of FIG. 7, simulated agents 710, 712, 714, 716, 718, and 719 are shown within the perception area 706 of the moving volume 700. The simulated agents 710, 712, 714, 716, 718, and 719 are spawned in the region 750 and then behave within the moving volume 700 to achieve one or more goals. As shown in FIG. 7, simulated agents 710, 712, 714, and 716 are pedestrians. Simulated agent 718 is a cyclist, and simulated agent 719 is a vehicle. In examples, the simulated agents are intelligent simulated agents that achieve respective goals according to respective simulated agent models. In examples, the simulated agents are drones that operate under the control of a hivemind controller. The intelligent simulated agents and drone simulated agents are aware of other objects and features of the environment, including the simulated vehicle 702. Accordingly, the simulated agents 710, 712, 714, 716, 718, and 719 do not collide with each other and do not bisect each other. In examples, the simulated agents move to avoid collisions with other simulated agents.

In some embodiments, the simulated agents are goal oriented simulated agents that behave according to respective behavior models. For example, intelligent simulated agents have personalities, such as aggressive, cautious, and nominal. In examples, drone-like simulated agents are controlled by the hivemind controller to exhibit behaviors, such as aggressive, cautious, and nominal, as directed by the hivemind controller.

The moving volume 700 moves through the simulated environment with the simulated vehicle 702 at the center. In some embodiments, the size of the volume is fixed relative to the vehicle based on the radius 120. For example, the radius is static and remains the same during simulation. In some embodiments, the radius is dynamic and changes responsive to features of the vehicle. The perception area 706 is defined by the radius 720 extending from the simulated vehicle 702. A dynamic radius changes responsive to features of the vehicle. For example, the faster the vehicle travels during simulation, the larger the radius 720. Conversely, the slower the simulated vehicle 702 travels during simulation, the smaller the radius 720. In some embodiments the radius (and consequently the size of the moving volume) is determined based on time of day, locations defined by the seed, and the like. In examples, the radius is larger during the day, imitating a greater perception range available to real world vehicles during the daytime under ideal lighting conditions. Conversely, the radius is smaller at night, imitating a lower perception range available to real world vehicles during the nighttime under reduced lighting conditions. Similarly, the radius is smaller during poor weather conditions, imitating a lower perception range available to real world vehicles during poor weather conditions, such as rain, snow, and the like.

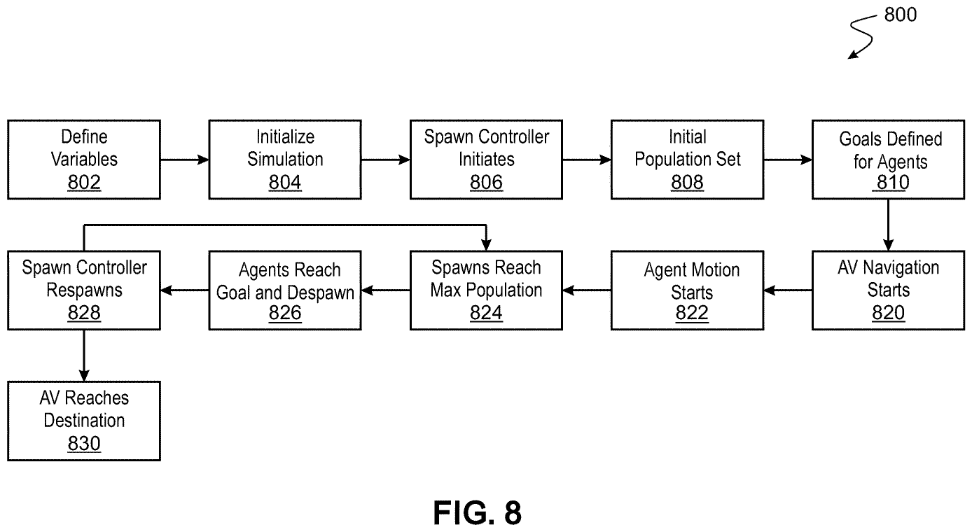

FIG. 8 is a workflow 800 for generating agents relative to a simulated autonomous vehicle. In some embodiments, one or more of the steps described with respect to workflow 800 are performed (e.g., completely, partially, and/or the like) autonomous vehicle (AV) system 114, fleet management system 116 described in FIG. 1, vehicle 200 of FIG. 2, device 300 of FIG. 3, autonomous vehicle compute 400 of FIG. 4, AV compute 504 of FIG. 5, or a testing infrastructure 600 of FIG. 6.

At block 802, variables associated with the simulation are defined. In examples, variables include parameters (e.g., a volume, an simulated agent type, and an simulated agent density of a simulated environment) and other values that define the scenario. For example, the scenario is specified by setting one or more values of the scenario. Additionally, in examples the moving volume is defined based on an initial radius (e.g., radius 720 of FIG. 7). The initial radius determines the size of a perception area (e.g., area 706 of FIG. 7) and a maximum extent area (e.g., area 708 of FIG. 7) of the moving volume. In some embodiments, the area is based on a detection range of one or more sensors according to a speed of the simulated vehicle. Accordingly, the size of the moving volume is based on a speed of the simulated vehicle. In examples, an simulated agent density and simulated agent types are specified for the moving volume. The simulated agent density refers to the number of simulated agents within the moving volume. In examples, the simulated agent density is static during the simulation, and simulated agents are spawned and despawned to maintain the static simulated agent density. In examples, the simulated agent density is dynamic during the simulation, and the simulated agents are spawned and despawned to maintain varying simulated agent densities over time. The simulated agent type refers to the categories of simulated agents within the moving volume. In examples, simulated agent types include, but are not limited to, vehicles, trucks (e.g., small trucks, large trucks, tractor-trailers), pedestrians, cyclists, structures (e.g., a building, a sign, a fire hydrant, road block, etc.), and/or the like. In examples, the simulated agent type is static during the simulation, and simulated agents are spawned and despawned according to the static simulated agent type. In examples, the simulated agent type is dynamic during the simulation, and the simulated agents are spawned and despawned to maintain varying simulated agent types over time. The simulated agent type can, for example, change according to features of the environment, such as the time of day, (e.g., a larger number of pedestrians are out during the day as opposed to at night), based on weather conditions, or based on location (e.g., more pedestrians are available in an urban center as opposed to the outskirts of the urban center). In examples, the simulated agent types in the volume are specified by percentages at one or more time stamps in the simulation. For example, upon initialization, the simulated agent types are 70% pedestrian, 5% cyclists, and 25% vehicles. In some embodiments, defining variables also includes defining simulated agent behavior.

In some embodiments, defining variables also includes defining traffic maneuvers to be performed by the simulated agents. For example, traffic maneuvers include a number of cut-ins from vehicles on the road, where vehicles unexpectedly enter the simulated vehicle's lane of traffic. Traffic maneuvers also include right-of-way errors (where a vehicle disobeys the standard right of way). Pedestrian and cyclist maneuvers are also defined, such as jaywalkers and pedestrians entering the path of the simulated vehicle. Additional variables include an amount of distance between simulated agents when spawned, a response time of the simulated agents, and the like. As such, defining variables enables the specification of the scenario.

At block 804, the simulation is initialized. In examples, initialization refers to setting environmental data associated with the simulation to an initial value as specified by a scenario and according to the variables defined at block 802. At block 806, a spawn controller is initialized using a seed value and according to the variables defined at block 802. In some embodiments, the seed is deterministic. In some embodiments, the seed is non-deterministic. Initialization of the spawn controller is used to generate an initial population set at block 808. In examples, the initial population set is the first set of simulated agents generated according to the seed value and the variables defined at block 802. Additionally, goals are defined for the simulated agents of the initial population set. In examples, the initial population set is based on the spawn controller taking in the variables that were defined at block 802 and filling the volume with randomly generated traffic. In some examples, blocks 802, 804, 806, 808, and 810 are performed simultaneously or substantially simultaneously to initialize a scenario.

At block 820, AV navigation begins. For example, AV navigation begins with the AV motion in the simulated environment. At block 822, simulated agent motion begins. In some embodiments, the AV navigation and action motion start simultaneously or substantially simultaneously. At blocks 824, 826, and 828, a loop in the workflow 800 occurs until the AV reaches its destination at block 830. At block 824, simulated agents are spawned to maintain a maximum population within the perception volume as the AV moves in the simulation. As the AV moves in the scenario along its route, simulated agents despawn as provided at block 826. In examples, the simulated agents despawn when outside of the moving volume, which may occur before the simulated agents reach their goal. In examples, in response to the population of simulated agents dropping below a predefined threshold, at block 828 the spawn controller spawns new simulated agents. The loop across blocks 824, 826, and 828 continues as the moving volume moves through the simulated environment. The loop across blocks 824, 826, and 828 continues until the AV reaches its destination or the simulation ends for some other reason, such as a traffic conflict or a simulation halt.

In examples, the spawning/despawning loop, including blocks 824, 826, and 828, is dynamic, and features of the spawning/despawning change. For example, when the moving volume is near certain landmarks, such as a bus station, a subway entrance, or at various pickup drop off zones, the simulated agent density, simulated agent types, simulated agent behavior, and the like change to reflect the types of traffic and simulated agents near those landmarks. Additionally, the time of day can affect the agent density, agent types, and agent behavior. For example, the Las Vegas Strip represents an urban area heavily populated with vehicles, pedestrians, and cyclists during the day. However, at night (e.g., 4 AM) traffic is reduced. A simulation includes a reduced simulated agent density to randomly imitate patterns of the Las Vegas Strip.

In examples, the present techniques enable multiple simulations that execute simultaneously to test a command center. For example, a command center distributes routes to a fleet of simulated vehicles, each with a respective assigned route. The simulated fleet of vehicles are, for example, autonomous vehicles that operate in an urban center such as the Las Vegas Strip. Each respective simulation includes random traffic generation to simulate real-world environments.

The spawning and despawning of simulated agents in a moving volume enables a realistic environment that is less computationally intensive when compared to generating traffic along the entire route traversed by a simulated vehicle. In some cases, creating a scenario includes manually inserting traffic along a route traversed by a simulated vehicle. Manual specification of the scenario is a time-consuming process. The present techniques reduce the time it takes to create realistic scenarios by eliminating the need to manually set each aspect of the scenario. Hundreds of resource hours go into specifying manual scenarios, and manual specification is not feasible when a large number of simulations are executed.

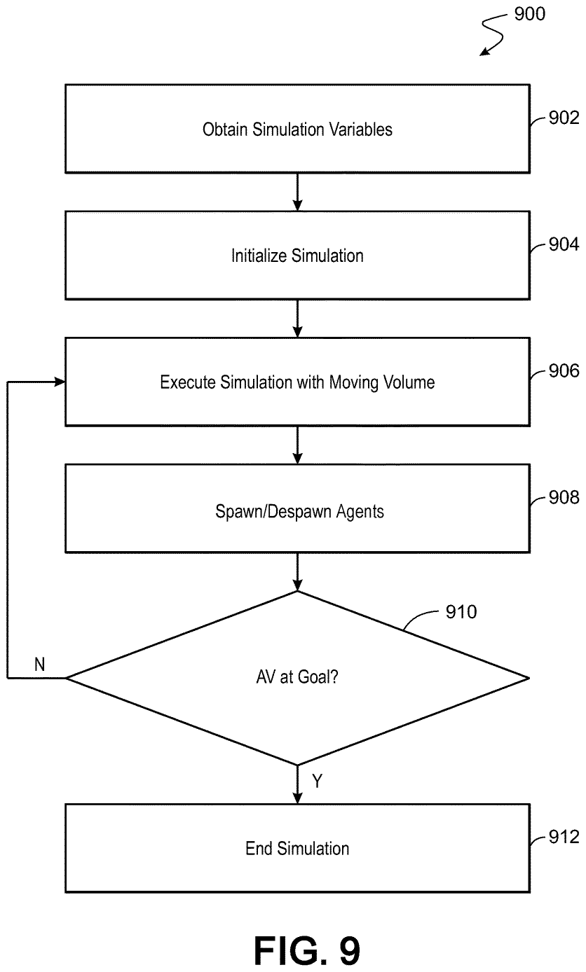

FIG. 9 is a process flow diagram of a process 900 that enables generating agents relative to a simulated autonomous vehicle. In some embodiments, one or more of the steps described with respect to the process 900 are performed (e.g., completely, partially, and/or the like) autonomous vehicle (AV) system 114, fleet management system 116 described in FIG. 1, vehicle 200 of FIG. 2, device 300 of FIG. 3, autonomous vehicle compute 400 of FIG. 4, AV compute 504 of FIG. 5, or a testing infrastructure 600 of FIG. 6.

At block 902, simulation variables are obtained. In examples, the simulation variables of a simulation comprising a volume, simulated agent types, and an simulated agent density of a simulated environment including a simulated vehicle. In examples, the simulation variables also include an simulated agent behavior.

At block 904, the simulation is initialized using a seed that identifies at least a starting location and a goal location of the simulation. In some embodiments, goals are assigned to simulated agents within the volume, and a size of the volume is variable. Simulated agents are spawned within the volume during simulation to accomplish respective goals. In some examples, a spawn pattern is based on randomly selected seed. For example, the seed is randomly selected by the simulation and used to specify an initial set of simulated agents with associated characteristics such as goals, movement patterns such as gait (e.g., pattern of movement or lack thereof), cadence (e.g., the number of steps pre minute), and the like. Additional simulated agents with associated characteristics are randomly spawned during a simulation based on the randomly selected seed. Accordingly, the randomly selected seed is nondeterministic. In examples, the randomly selected seed is used in multiple executions and is a deterministic seed. In some embodiments, a spawn pattern is based on a deterministic seed that specifies predetermined simulated agents and their associated characteristics throughout a simulation. The simulated agents spawned during the simulation are specified by the seed at predetermined locations and timestamps of the simulation. In some embodiments, a null seed is selected and the spawn pattern during the simulation is random across multiple executions of the simulation.

At block 906, the simulation is executed with a moving volume. During execution of a simulation, the simulated vehicle navigates from a starting location to a goal location in a scenario, and the moving volume is updated responsive to motion of the simulated vehicle (e.g., spawn area that is a variable range around AV). At block 908, simulated agents are spawned and despawned, and the simulated agents traverse the environment within the moving volume to achieve at least one goal.

At block 910 it is determined if the simulated vehicle is at the goal location. If the simulated vehicle is not at the goal location, process flow returns to block 906 where the simulation is executed with the moving volume. If the simulated vehicle is at the goal location, process flow continues to block 912 where the simulation ends.

According to some non-limiting embodiments or examples, provided is a method, comprising determining, using at least one processor, parameters of a simulation comprising a volume, an simulated agent type, and an simulated agent density of a simulated environment, the simulated environment comprising a simulated vehicle; initiating, using the at least one processor, the simulation based on a seed that identifies at least a starting location and a goal location of the simulation; assigning, using the at least one processor, goals to simulated agents within the volume, wherein the simulated agents are spawned within the volume during execution of simulation to accomplish respective goals based on the parameters and the seed; and executing, using the at least one processor, the simulation, wherein the simulated vehicle navigates from the starting location to the goal location and the volume is updated responsive to motion of the simulated vehicle.

According to some non-limiting embodiments or examples, provided is a system, comprising: at least one computer-readable medium storing computer-executable instructions; at least one processor communicatively coupled to the at least one computer-readable medium and configured to execute the computer executable instructions, the execution carrying out operations including: determining parameters of a simulation comprising a volume, simulated agent type, and an simulated agent density of a simulated environment comprising a simulated vehicle; initiating the simulation based on a seed that identifies at least a starting location and a goal location of the simulation; assigning goals to simulated agents within the volume, wherein the simulated agents are spawned within the volume during execution of simulation to accomplish respective goals based on the parameters and the seed; and executing the simulation, wherein the simulated vehicle navigates from the starting location to the goal location and the volume is updated responsive to motion of the simulated vehicle.

According to some non-limiting embodiments or examples, provided is at least one non-transitory storage media storing instructions that, when executed by at least one processor, cause the at least one processor to: determine parameters of a simulation comprising a volume, an simulated agent type, and an simulated agent density of a simulated environment, the simulated environment comprising a simulated vehicle; initiate the simulation based on a seed that identifies at least a starting location and a goal location of the simulation; assign goals to simulated agents within the volume, wherein the simulated agents are spawned within the volume during execution of simulation to accomplish respective goals based on the seed and the parameters; and execute the simulation, wherein the simulated vehicle navigates from the starting location to the goal location and the volume is updated responsive to motion of the simulated vehicle.

Further non-limiting aspects or embodiments are set forth in the following numbered clauses:

Clause 1: A method, including determining, using at least one processor, parameters of a simulation comprising a volume, an simulated agent type, and an simulated agent density of a simulated environment, the simulated environment comprising a simulated vehicle; initiating, using the at least one processor, the simulation based on a seed that identifies at least a starting location and a goal location of the simulation; assigning, using the at least one processor, goals to simulated agents within the volume, wherein the simulated agents are spawned within the volume during execution of simulation to accomplish respective goals based on the parameters and the seed; and executing, using the at least one processor, the simulation, wherein the simulated vehicle navigates from the starting location to the goal location and the volume is updated responsive to motion of the simulated vehicle.

Clause 2: The method of clause 1, comprising updating a size of the volume according to a dynamic radius that extends from the vehicle, the dynamic radius corresponding to a perception area associated with the vehicle at a timestep.

Clause 3: The method of clauses 1 or 2, further comprising iteratively updating the volume during execution of the simulation by spawning additional simulated agents at locations within the volume as the simulated vehicle navigates from the starting location to the goal location.

Clause 4: The method of any of clauses 1-3, further comprising evaluating operation of the simulated vehicle according to vehicle behavior during execution of the simulation.

Clause 5: The method of any of clauses 1-4, wherein initiating the simulation based on the seed comprises initiating the simulation based on a deterministic seed.

Clause 6: The method of any of clauses 1-4, wherein initiating the simulation based on the seed comprises initiating the simulation based on a nondeterministic seed.

Clause 7: The method of any of clauses 1-6, wherein assigning the goals to the simulated agents within the volume comprises assigning the goals to the simulated agents based on a context of the simulation.

Clause 8: The method of any of clauses 1-7, further comprising updating a simulated agent density as the volume moves through the simulated environment based on a context of the simulation, wherein the context comprises at least a time of day associated with the simulation.

Clause 9: The method of any of clauses 1-8, wherein a respective simulated agent within the volume moves based on locations of other simulated agents in the simulated environment as the other simulated agents accomplish the respective goals during the simulation, wherein the respective simulated agent avoids collisions with the other simulated agents.

Clause 10: A system, including: at least one computer-readable medium storing computer-executable instructions; at least one processor communicatively coupled to the at least one computer-readable medium and configured to execute the computer executable instructions, the execution carrying out operations including: determining parameters of a simulation comprising a volume, simulated agent type, and an simulated agent density of a simulated environment comprising a simulated vehicle; initiating the simulation based on a seed that identifies at least a starting location and a goal location of the simulation; assigning goals to simulated agents within the volume, wherein the simulated agents are spawned within the volume during execution of simulation to accomplish respective goals based on the parameters and the seed; and executing the simulation, wherein the simulated vehicle navigates from the starting location to the goal location and the volume is updated responsive to motion of the simulated vehicle.

Clause 11: The system of clause 10, comprising updating a size of the volume according to a dynamic radius that extends from the vehicle, the dynamic radius corresponding to a perception area associated with the vehicle at a timestep.

Clause 12: The system of clauses 10 or 11, further comprising: iteratively updating the volume during execution of the simulation by spawning additional simulated agents at locations within the volume as the simulated vehicle navigates from the starting location to the goal location.

Clause 13: The system of any of clauses 10-12, further comprising a spawn controller that receives the determined parameters and spawns simulated agents according to the parameters upon initialization of the simulation.

Clause 14: The system of any of clauses 10-13, wherein the seed specifies simulated agents to be spawned at predetermined locations and predetermined times during execution of the simulation.

Clause 15: The system of any of clauses 10-13, wherein the seed specifies random simulated agent generation at random locations and random times during execution of the simulation.

Clause 16: At least one non-transitory storage media storing instructions that, when executed by at least one processor, cause the at least one processor to: determine parameters of a simulation comprising a volume, an simulated agent type, and an simulated agent density of a simulated environment, the simulated environment comprising a simulated vehicle; initiate the simulation based on a seed that identifies at least a starting location and a goal location of the simulation; assign goals to simulated agents within the volume, wherein the simulated agents are spawned within the volume during execution of simulation to accomplish respective goals based on the seed and the parameters; and execute the simulation, wherein the simulated vehicle navigates from the starting location to the goal location and the volume is updated responsive to motion of the simulated vehicle.

Clause 17: The least one non-transitory storage media of clause 16, comprising updating a size of the volume according to a dynamic radius that extends from the vehicle, the dynamic radius corresponding to a perception area associated with the vehicle at a timestep.

Clause 18: The least one non-transitory storage media of clauses 16 or 17, wherein the volume is iteratively updated during execution of the simulation by spawning additional simulated agents at locations within the volume as the simulated vehicle navigates from the starting location to the goal location.

Clause 19: The least one non-transitory storage media of any of clauses 16-18, further comprising evaluating operation of the simulated vehicle according to vehicle behavior during execution of the simulation.

Clause 20: The least one non-transitory storage media of any of clauses 16-19, wherein the simulated agents are spawned outside of a perception area of the volume and within a maximum extent area of the volume.

In the foregoing description, aspects and embodiments of the present disclosure have been described with reference to numerous specific details that can vary from implementation to implementation. Accordingly, the description and drawings are to be regarded in an illustrative rather than a restrictive sense. The sole and exclusive indicator of the scope of the invention, and what is intended by the applicants to be the scope of the invention, is the literal and equivalent scope of the set of claims that issue from this application, in the specific form in which such claims issue, including any subsequent correction. Any definitions expressly set forth herein for terms contained in such claims shall govern the meaning of such terms as used in the claims. In addition, when we use the term “further comprising,” in the foregoing description or following claims, what follows this phrase can be an additional step or entity, or a sub-step/sub-entity of a previously-recited step or entity.

What is claimed is:

1. A method, comprising:
determining, using at least one processor, parameters of a simulation comprising a volume, an simulated agent type, and an simulated agent density of a simulated environment, the simulated environment comprising a simulated vehicle;
initiating, using the at least one processor, the simulation based on a seed that identifies at least a starting location and a goal location of the simulation;
assigning, using the at least one processor, goals to simulated agents within the volume, wherein the simulated agents are spawned within the volume during execution of simulation to accomplish respective goals based on the parameters and the seed; and
executing, using the at least one processor, the simulation, wherein the simulated vehicle navigates from the starting location to the goal location and the volume is updated responsive to motion of the simulated vehicle.

2. The method of claim 1, comprising updating a size of the volume according to a dynamic radius that extends from the vehicle, the dynamic radius corresponding to a perception area associated with the vehicle at a timestep.

3. The method of claims 1 or 2, further comprising: iteratively updating the volume during execution of the simulation by spawning additional simulated agents at locations within the volume as the simulated vehicle navigates from the starting location to the goal location.

4. The method of any of claims 1-3, further comprising evaluating operation of the simulated vehicle according to vehicle behavior during execution of the simulation.

5. The method of any of claims 1-4, wherein initiating the simulation based on the seed comprises initiating the simulation based on a deterministic seed.

6. The method of any of claims 1-4, wherein initiating the simulation based on the seed comprises initiating the simulation based on a nondeterministic seed.

7. The method of any of claims 1-6, wherein assigning the goals to the simulated agents within the volume comprises assigning the goals to the simulated agents based on a context of the simulation.

8. The method of any of claims 1-7, further comprising updating a simulated agent density as the volume moves through the simulated environment based on a context of the simulation, wherein the context comprises at least a time of day associated with the simulation.

9. The method of any of claims 1-8, wherein a respective simulated agent within the volume moves based on locations of other simulated agents in the simulated environment as the other simulated agents accomplish the respective goals during the simulation, wherein the respective simulated agent avoids collisions with the other simulated agents.

10. A system, comprising:
at least one computer-readable medium storing computer-executable instructions;
at least one processor communicatively coupled to the at least one computer-readable medium and configured to execute the computer executable instructions, the execution carrying out operations including:
determining parameters of a simulation comprising a volume, simulated agent type, and an simulated agent density of a simulated environment comprising a simulated vehicle;
initiating the simulation based on a seed that identifies at least a starting location and a goal location of the simulation;
assigning goals to simulated agents within the volume, wherein the simulated agents are spawned within the volume during execution of simulation to accomplish respective goals based on the parameters and the seed; and
executing the simulation, wherein the simulated vehicle navigates from the starting location to the goal location and the volume is updated responsive to motion of the simulated vehicle.

11. The system of claim 10, comprising updating a size of the volume according to a dynamic radius that extends from the vehicle, the dynamic radius corresponding to a perception area associated with the vehicle at a timestep.

12. The system of claims 10 or 11, further comprising:
iteratively updating the volume during execution of the simulation by spawning additional simulated agents at locations within the volume as the simulated vehicle navigates from the starting location to the goal location.

13. The system of any of claims 10-12, further comprising a spawn controller that receives the determined parameters and spawns simulated agents according to the parameters upon initialization of the simulation.

14. The system of any of claims 10-13, wherein the seed specifies simulated agents to be spawned at predetermined locations and predetermined times during execution of the simulation.

15. The system of any of claims 10-13, wherein the seed specifies random simulated agent generation at random locations and random times during execution of the simulation.

16. At least one non-transitory storage media storing instructions that, when executed by at least one processor, cause the at least one processor to:
determine parameters of a simulation comprising a volume, a simulated agent type, and an simulated agent density of a simulated environment, the simulated environment comprising a simulated vehicle;
initiate the simulation based on a seed that identifies at least a starting location and a goal location of the simulation;
assign goals to simulated agents within the volume, wherein the simulated agents are spawned within the volume during execution of simulation to accomplish respective goals based on the seed and the parameters; and
execute the simulation, wherein the simulated vehicle navigates from the starting location to the goal location and the volume is updated responsive to motion of the simulated vehicle.

17. The least one non-transitory storage media of claim 16, comprising updating a size of the volume according to a dynamic radius that extends from the vehicle, the dynamic radius corresponding to a perception area associated with the vehicle at a timestep.

18. The least one non-transitory storage media of claims 16 or 17, wherein the volume is iteratively updated during execution of the simulation by spawning additional simulated agents at locations within the volume as the simulated vehicle navigates from the starting location to the goal location.

19. The least one non-transitory storage media of any of claims 16-18, further comprising evaluating operation of the simulated vehicle according to vehicle behavior during execution of the simulation.

20. The least one non-transitory storage media of any of claims 16-19, wherein the simulated agents are spawned outside of a perception area of the volume and within a maximum extent area of the volume.
